(19) United States
(12) Patent Application Publication
(10) Pub. No.: US 2025/0240021 A1
(43) Pub. Date: Jul. 24, 2025

(54) PHYSICALLY UNCLONABLE CELL WITH SINGLE TRANSISTOR TYPES TO IMPROVE VOLTAGE AND TEMPERATURE STABILITY

(71) Applicant: NVIDIA Corp., Santa Clara, CA (US)

(72) Inventors: Mahmut Ersin Sinangil, Los Altos, CA (US); Sudhir Shrikantha Kudva, Dublin, CA (US); Nikola Nedovic, San Jose, CA (US); John Poulton, Chapel Hill, NC (US); Carl Thomas Gray, Apex, NC (US)

(73) Assignee: NVIDIA Corp., Santa Clara, CA (US)

(21) Appl. No.: 18/419,153

(22) Filed: Jan. 22, 2024

(51) Int. Cl. H03K 19/17768; H03K 19/0944; H03K 19/17784

(52) U.S. Cl. CPC H03K 19/17768; H03K 19/0944; H03K 19/17784

(57) ABSTRACT

Physically unclonable function cells based on bit-storing machine-memory circuits include a pair of parallel circuit branches, each of the parallel branches including a first transistor configured to be always-ON when the physically unclonable function cell is powered, and a second transistor cross-coupled to an opposite one of the parallel branches.

### BACKGROUND

Physically Unclonable Function (PUF) cells are utilized in secure devices that employ hardware root-of-trust to generate a key value (e.g., for encryption) unique to an integrated circuit or device. Although in theory a physically unclonable function cell might be “cloned”, in practice it is impractically difficult for bad-intentioned actors to do so. PUF cells utilize subtle manufacturing process variations to generate keys which are highly immune to physical tampering and optical or electrical probing. An important consideration for PUF cell design is the effect of voltage and temperature variations on the PUF output. A satisfactory PUF cell should exhibit stable and reproduceable outputs across different voltage and temperature conditions in noisy environments.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 depicts PUF array outputs applied to generate a key value, in accordance with one embodiment.

FIG. 2 depicts a conventional physically unclonable function cell.

FIG. 3A depicts an embodiment of a PUF cell implemented using exclusively NMOS type transistors.

FIG. 3B depicts an embodiment of a PUF cell implemented using exclusively PMOS type transistors.

FIG. 4A depicts an embodiment of an NMOS-type physically unclonable function cell with feedback to reduce power consumption.

FIG. 4B depicts signaling in a PUF cell embodiment.

FIG. 4C depicts an embodiment of a PMOS-type physically unclonable function cell with feedback to reduce power consumption.

FIG. 5 depicts the utilization of headers, footers, and control logic in a PUF cell array in one embodiment.

### DETAILED DESCRIPTION

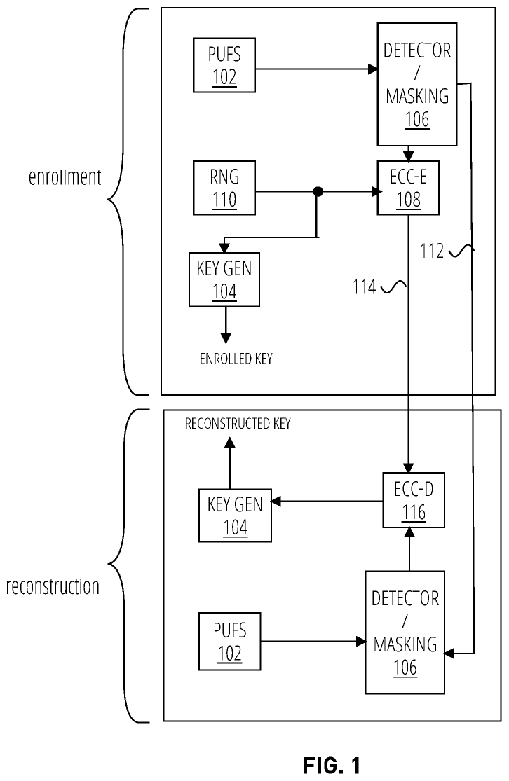

FIG. 1 depicts an exemplary application of physically unclonable function cells. During enrollment, outputs from an array of the physically unclonable cells 102 are applied to a key generator 104 to create a key value. Each physically unclonable cell 102 output is typically one binary ‘bit’.

The outputs of the array of physically unclonable cells 102 are tested by instability detection and masking logic 106 and unsuitable outputs are removed from use in the key generator 104. Suitable PUF cell outputs will exhibit high entropy (randomness) with respect to process variations but will remain consistent across voltage and temperature variations; the instability detection and masking logic 106 masks (blocks or otherwise removes) PUF cell outputs that don't satisfy these conditions. The instability detection and masking logic 106 may perform de-biasing as well as dark bit detection and masking to increase entropy of the remaining cells and reduce instability. An ECC encoder 108 and ring oscillator 110 are applied to the suitable PUF outputs to further protect against instability induced bit errors due to voltage and temperature changes.

Once the physically unclonable cells 102 that generate suitable, stable outputs are identified and enrolled, they may be utilized to generate device-specific keys for authorization, authentication, or other purposes. The bits generated by the enrolled physically unclonable cells 102 are again tested and masked (utilizing for example mask settings 112 generated during enrollment), and the ECC code 114 generated during enrollment is utilized by an ECC decoder 116 to detect and, if possible, correct any induced bit errors due to voltage and temperature fluctuations. The key is then reconstructed from the resulting bits.

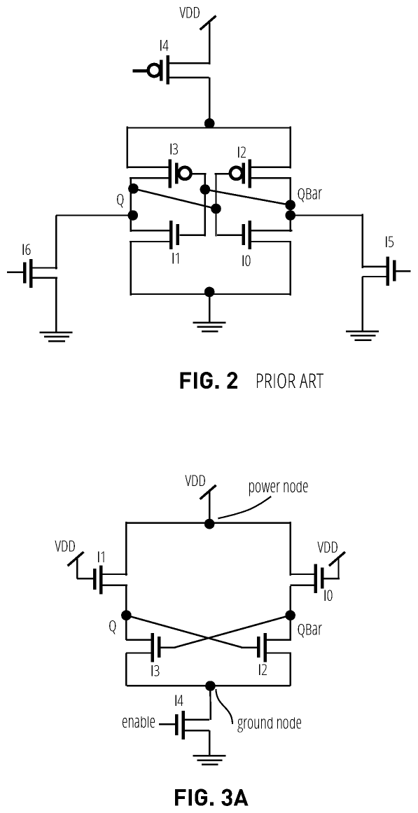

FIG. 2 depicts a conventional physically unclonable function cell. This type of cell is based on a static random access memory circuit for storing a bit value. The cell comprises two cross-coupled inverters (I0-I3), each comprising both NMOS and PMOS type devices.

The cell further comprises NMOS devices that may be operated to initialize the cell (I5-I6), and a header device (I4). During reset (reset=1), storage nodes of this structure (Q and QBar) are initialized to ‘0’ and I4 is off. When the reset signal goes low (reset=1→0), the inverters are energized and the mismatches across these devices determine whether the internal state resolves to Q=‘0’/QBar=‘1’ or Q=‘1’/QBar=‘0’.

Structurally the SRAM embodiment of a physically unclonable function cell appears completely symmetrical. In operation, each transistor device exhibits slightly different electrical characteristics due to manufacturing process variation. Consequently, the internal state of the cell resolves to some preferred state during power up or after a reset.

A drawback of this type of PUF cell is that voltage and temperature changes on a given cell affect each the different transistor types (PMOS or NMOS) differently, resulting in potentially variable resolved states, depending on the ambient and/or operational temperature of the device comprising the PUF cells, and on variations in supply voltage. which causes preferred state to change with voltage and temperature.

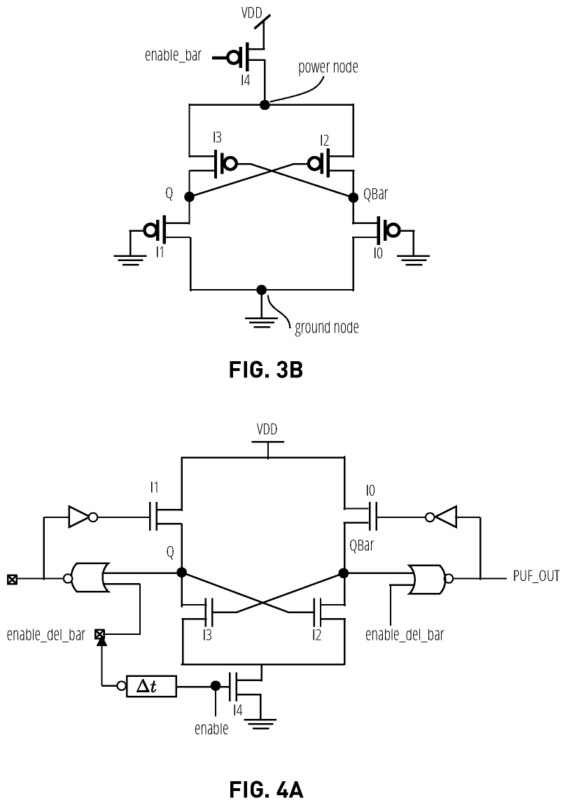

FIG. 3A depicts an embodiment of a PUF cell implemented using exclusively NMOS type transistors. FIG. 3B depicts an embodiment of a PUF cell implemented using exclusively PMOS type transistors.

In both embodiments, devices I0 and I1 are configured to be always-ON and function as a resistive load. Also in both embodiment, I2 and I3 implement differential pairs that drive the outputs, and I4 functions as a switch to enable and disable the PUF cell.

When the enable signal goes high in the NMOS type PUF cell of FIG. 3A, or the enable_bar signal goes low in the PMOS type PUF cell of FIG. 3B, the strength of transistor I0-I3 determines the equilibrium state into which the PUF cell resolves.

In each embodiment, voltage and temperature change have a smaller impact on this preferred state due to the uniform type of all transistors utilized in the cell. Some process variation is still present among transistors of the same type, resulting in small differences in electrical characteristics among individual devices within the cell and giving rise to some residual voltage and temperature variations. However the overall voltage and temperature variability in equilibrium state may be substantially reduced over that exhibited in conventional memory-cell-based PUF cell configurations.

The decision whether to implement the PUF cells as NMOS-only types or PMOS-only types may depend on the process technology characteristics that these PUF cells are fabricated on. Factors that may affect this decision include the voltage and temperature variations expected to occur in the location where the PUF cell transistors are disposed, aging profiles for the PUF cells, and local vs global voltage and temperature mismatch distributions in the device in which the PUF cells are deployed. In general, a PUF cell array to generate key values may include exclusively NMOS-only cells, exclusively PMOS-only cells, or a combination of both types in any ratio best suited to the application.

The physically unclonable function cell embodiments of FIG. 3A and FIG. 3B are based on machine-memory cell circuits, more specifically bit-storing cells. They each include a pair of parallel branches; each of the branches including a transistor configured to be always-ON (I0 and I1) when the cell is powered, and another transistor cross-coupled to (having a gate driven by) the opposite branch. The branches converge at a power node and a ground node (which is not necessarily a common location in the physical circuit, generally, although it often is).

One of the cross-coupled transistors is arranged in series with a corresponding always-ON transistor in each of the parallel branches, and the cross-coupled transistors and the always-ON transistors are all a same MOS type. In the embodiment of FIG. 3B the always-ON transistors comprise grounded-gate PMOS transistors (the gates being tied to ground potential). In the embodiment of FIG. 3A, the always-ON transistors comprise NMOS transistors with their gates connected to the power supply of the physically unclonable function cell.

In the NMOS-only embodiment, the footer transistor may be operated to enable the physically unclonable function cell (activate current flow to cause the cell to settle to an equilibrium state). In the PMOS-only embodiment, a header transistor is operable to enable the cell.

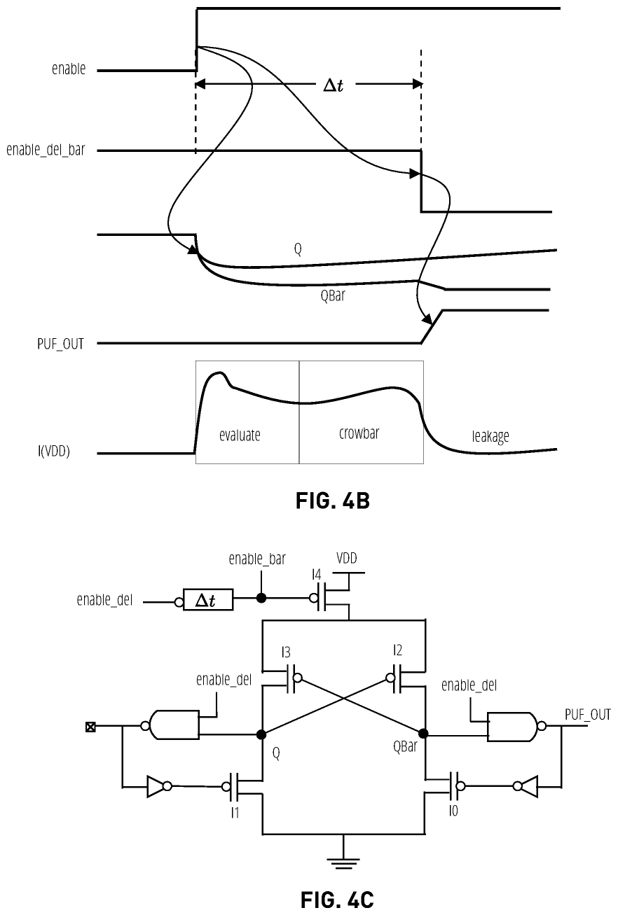

FIG. 4A depicts an embodiment of an NMOS-type physically unclonable function cell with feedback to reduce power consumption. FIG. 4C depicts an embodiment of a PMOS-type physically unclonable function cell with feedback to reduce power consumption. The utilization of a single device type in these cell structures reduces instability, but may lead to increases in power consumption due to crowbar or leakage current when both I0 and I2, or I1 and I3, are turned ON simultaneously (see FIG. 4B).

By utilizing feedback, and footer and header devices, the embodiments depicted in FIG. 4A and FIG. 4C mitigate these effects. In these structures, when both I0 and I2, or I1 and I3, are turned ON simultaneously, substantial current flows only occur only during intervals when the enable signal (or enable_bar for PMOS-type cells) is also asserted, activating the header or footer devices, respectively. enabled, i.e. footer/header is ON. The feedback paths are operated on a delayed version of the signal that activates the header or footer devices, ensuring that the higher current state of the cells is active only for a brief interval (approximately At). The interval may be configured either statically (“hard-wired”) or dynamically (an re-configurable operational setting).

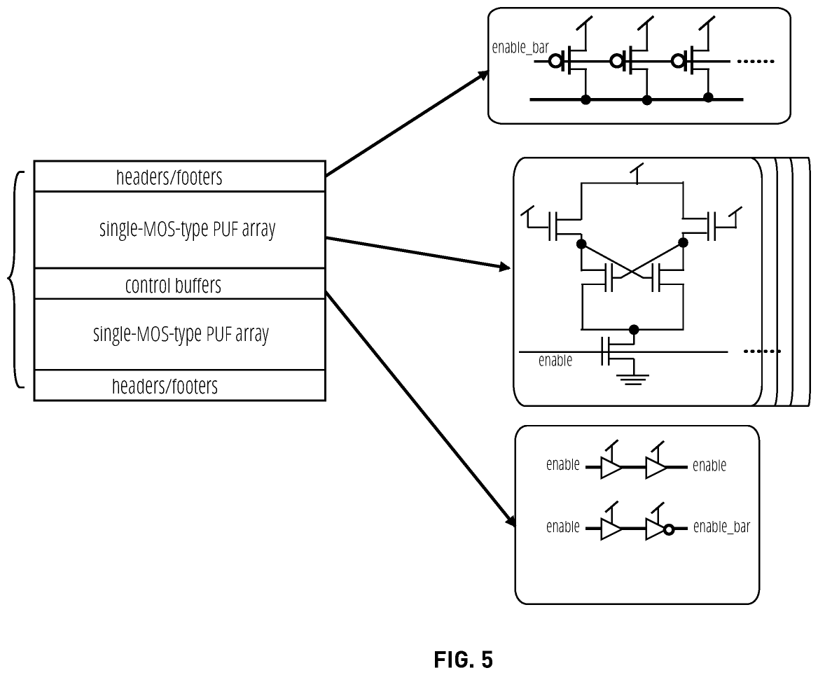

The headers and/or footers may be implemented across the entire PUF array (see FIG. 5) with intervening delay stages, so that enrollment or reconstruction takes place sequentially across the array, avoiding large peak currents that might arise if the cells were activated simultaneously/in parallel.

### LISTING OF DRAWING ELEMENTS

102 physically unclonable cell
104 key generator
106 instability detection and masking logic
108 ECC encoder
110 ring oscillator
112 mask settings
114 ECC code
116 ECC decoder

Various functional operations described herein may be implemented in logic that is referred to using a noun or noun phrase reflecting said operation or function. For example, an association operation may be carried out by an “associator” or “correlator”. Likewise, switching may be carried out by a “switch”, selection by a “selector”, and so on. “Logic” refers to machine memory circuits and non-transitory machine readable media comprising machine-executable instructions (software and firmware), and/or circuitry (hardware) which by way of its material and/or material-energy configuration comprises control and/or procedural signals, and/or settings and values (such as resistance, impedance, capacitance, inductance, current/voltage ratings, etc.), that may be applied to influence the operation of a device. Magnetic media, electronic circuits, electrical and optical memory (both volatile and nonvolatile), and firmware are examples of logic. Logic specifically excludes pure signals or software per se (however does not exclude machine memories comprising software and thereby forming configurations of matter). Logic symbols in the drawings should be understood to have their ordinary interpretation in the art in terms of functionality and various structures that may be utilized for their implementation, unless otherwise indicated.

Within this disclosure, different entities (which may variously be referred to as “units,” “circuits,” other components, etc.) may be described or claimed as “configured” to perform one or more tasks or operations. This formulation-[entity] configured to [perform one or more tasks]-is used herein to refer to structure (i.e., something physical, such as an electronic circuit). More specifically, this formulation is used to indicate that this structure is arranged to perform the one or more tasks during operation. A structure can be said to be “configured to” perform some task even if the structure is not currently being operated. A “credit distribution circuit configured to distribute credits to a plurality of processor cores” is intended to cover, for example, an integrated circuit that has circuitry that performs this function during operation, even if the integrated circuit in question is not currently being used (e.g., a power supply is not connected to it). Thus, an entity described or recited as “configured to” perform some task refers to something physical, such as a device, circuit, memory storing program instructions executable to implement the task, etc. This phrase is not used herein to refer to something intangible.

The term “configured to” is not intended to mean “configurable to.” An unprogrammed FPGA, for example, would not be considered to be “configured to” perform some specific function, although it may be “configurable to” perform that function after programming.

Reciting in the appended claims that a structure is “configured to” perform one or more tasks is expressly intended not to invoke 35 U.S.C. § 112(f) for that claim element. Accordingly, claims in this application that do not otherwise include the “means for” [performing a function] construct should not be interpreted under 35 U.S.C § 112(f).

As used herein, the term “based on” is used to describe one or more factors that affect a determination. This term does not foreclose the possibility that additional factors may affect the determination. That is, a determination may be solely based on specified factors or based on the specified factors as well as other, unspecified factors. Consider the phrase “determine A based on B.” This phrase specifies that B is a factor that is used to determine A or that affects the determination of A. This phrase does not foreclose that the determination of A may also be based on some other factor, such as C. This phrase is also intended to cover an embodiment in which A is determined based solely on B. As used herein, the phrase “based on” is synonymous with the phrase “based at least in part on.”

As used herein, the phrase “in response to” describes one or more factors that trigger an effect. This phrase does not foreclose the possibility that additional factors may affect or otherwise trigger the effect. That is, an effect may be solely in response to those factors, or may be in response to the specified factors as well as other, unspecified factors. Consider the phrase “perform A in response to B.” This phrase specifies that B is a factor that triggers the performance of A. This phrase does not foreclose that performing A may also be in response to some other factor, such as C. This phrase is also intended to cover an embodiment in which A is performed solely in response to B.

As used herein, the terms “first,” “second,” etc. are used as labels for nouns that they precede, and do not imply any type of ordering (e.g., spatial, temporal, logical, etc.), unless stated otherwise. For example, in a register file having eight registers, the terms “first register” and “second register” can be used to refer to any two of the eight registers, and not, for example, just logical registers 0 and 1.

When used in the claims, the term “or” is used as an inclusive or and not as an exclusive or. For example, the phrase “at least one of x, y, or z” means any one of x, y, and z, as well as any combination thereof.

As used herein, a recitation of “and/or” with respect to two or more elements should be interpreted to mean only one element, or a combination of elements. For example, “element A, element B, and/or element C” may include only element A, only element B, only element C, element A and element B, element A and element C, element B and element C, or elements A, B, and C. In addition, “at least one of element A or element B” may include at least one of element A, at least one of element B, or at least one of element A and at least one of element B. Further, “at least one of element A and element B” may include at least one of element A, at least one of element B, or at least one of element A and at least one of element B.

Although the terms “step” and/or “block” may be used herein to connote different elements of methods employed, the terms should not be interpreted as implying any particular order among or between various steps herein disclosed unless and except when the order of individual steps is explicitly described.

Having thus described illustrative embodiments in detail, it will be apparent that modifications and variations are possible without departing from the scope of the intended invention as claimed. The scope of inventive subject matter is not limited to the depicted embodiments but is rather set forth in the following Claims.

What is claimed is:

1. A machine-memory cell comprising:
a pair of parallel branches;
each of the branches comprising:
a first transistor configured to be always-ON when the memory cell is powered; and
a second transistor cross-coupled to an opposite one of the branches.

2. The machine-memory cell of claim 1, wherein the branches join at a power node.

3. The machine-memory cell of claim 2, wherein the branches join at a grounded node.

4. The machine-memory cell of claim 1, wherein the first transistor and the second transistor are NMOS-type devices.

5. The machine-memory cell of claim 4, further comprising an NMOS-type footer transistor.

6. The machine-memory cell of claim 1, wherein the first transistor and the second transistor are PMOS-type devices.

7. The machine-memory cell of claim 6, further comprising a PMOS-type header transistor.

8. The machine-memory cell of claim 1, wherein each of the branches is coupled to a common power node.

9. A circuit comprising:
a plurality of physically unclonable function cells, each comprising a pair of transistors configured to be always-ON when power is applied to the physically unclonable function cell, and each comprising a pair of cross-coupled transistors; and
logic to selectively enroll the physically unclonable function cells for use in key generation.

10. The circuit of claim 9, wherein the transistors of any particular one of the physically unclonable function cells are exclusively a common MOS type.

11. The circuit of claim 9, further comprising:
feedback logic to automatically disable current flow through one or more of the physically unclonable function cells a configured delay after enabling the one or more physically unclonable function cells.

12. A physically unclonable function cell comprising:
a pair of cross-coupled transistors each arranged in series with a corresponding always-ON transistor in separate parallel branches; and
wherein the cross-coupled transistors and the always-ON transistors are all a same MOS type.

13. The physically unclonable function cell of claim 12, wherein the MOS type is NMOS.

14. The physically unclonable function cell of claim 12, wherein the MOS type is PMOS.

15. The physically unclonable function cell of claim 12, wherein the always-ON transistors are grounded-gate PMOS transistors.

16. The physically unclonable function cell of claim 12, wherein the always-ON transistors comprise grounded-gate PMOS transistors.

17. The physically unclonable function cell of claim 12, wherein the always-ON transistors comprise NMOS transistors gate-connected to a power supply of the physically unclonable function cell.

18. The physically unclonable function cell of claim 12, further comprising footer logic configured to enable the physically unclonable function cell.

19. The physically unclonable function cell of claim 12, further comprising header logic configured to enable the physically unclonable function cell.

20. The physically unclonable function cell of claim 12, wherein the separate parallel branches each extend between a power node and a ground node of the physically unclonable function cell.
